(19) United States
(12) Patent Application Publication
(10) Pub. No.: US 2006/0121741 A1
(43) Pub. Date: Jun. 8, 2006

(54) Device for supplying a solution onto a substrate and method for supplying the solution onto the substrate by using the same

(76) Inventor: Sang-Kyu Park, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/296,768

(22) Filed: Dec. 6, 2005

(30) Foreign Application Priority Data
Dec. 7, 2004 (KR) 2004-102487

(51) Int. Cl. H01L 21/31; H01L 21/469

(52) U.S. Cl. 438/758

(57) ABSTRACT

In a device for supplying a solution onto a substrate and a method for supplying the solution onto the substrate, the device includes a first nozzle supplying a thinner onto a substrate, a second nozzle supplying a photoresist composition onto the substrate, a first pipe connected to the first nozzle, a second pipe connected to the second nozzle and a temperature controlling part enclosing the first and second pipes. The second nozzle is provided in the first nozzle. The thinner, the photoresist composition and a temperature controlling medium flow through the first pipe, the second pipe and the temperature controlling part, respectively. The temperature controlling parts are intended to keep the temperatures of the thinner and the photoresist composition substantially constant at a predetermined temperature.

### BACKGROUND OF THE INVENTION

1. Cross-References to Related Applications

This application claims benefit of priority under 35 USC § 119 from Korean Patent Application No. 2004-102487 filed on Dec. 7, 2004, the disclosure of which is incorporated herein by reference in its entirety.

2. Field of the Invention

The present invention relates to a solution coating apparatus and a coating method. More particularly, the present invention relates to devices for coating semiconductor substrates, such as a silicon wafer, with a photoresist composition and a thinner in connection with photolithography and to a coating method using the devices.

3. Description of the Prior Art

Generally, semiconductor devices are manufactured using a series of complex steps including a fabricating process for forming an electrical circuit on a silicon wafer substrate, an electrical die sorting (EDS) process for testing electrical characteristics of the semiconductor device after the fabricating process, and a package process for packaging the semiconductor devices using an epoxy resin after separating the wafer into individual chips.

The fabricating process includes, inter alia, a depositing process for forming a layer on a wafer, a chemical mechanical polishing process for planarizing a surface of the layer, a photolithography process for forming a photoresist pattern on the layer, an etching process for forming a pattern having electrical characteristics in the surface of the layer using the photoresist pattern as a mask pattern, an implantation process for implanting ions into designated areas of the wafer, a cleaning process for removing particles from the wafer, a drying process for drying the wafer after the cleaning process, and a testing process for detecting defects of the layer or the pattern.

The photolithography process for forming the photoresist pattern on the wafer may include a coating process, a soft bake process, an exposure process, a development process and a hard bake process. The coating process may be performed to coat a semiconductor substrate with a photoresist composition in order to form the photoresist layer on the semiconductor substrate. The soft bake process may be performed to volatilize a solvent included in the photoresist layer. The exposure process and the development process may be performed to partially remove the photoresist layer to form a photoresist layer pattern. Finally, the hard bake process may be performed to harden the photoresist layer pattern.

In one method, the photoresist layer may be formed by providing the semiconductor substrate with the photoresist composition and rotating the semiconductor substrate at high speed. While the photoresist layer is being formed, however, it is preferable that a temperature of the photoresist composition supplied onto the semiconductor substrate be kept constant at a predetermined temperature—e.g., at about 23° C.—because the thickness of the photoresist layer across the wafer surface varies in accordance with the temperature of the photoresist composition used. Varying temperatures may result in a non-uniform thickness of the photoresist layer and consequent problems in photolithography process.

Conventional devices used for coating the substrate with the photoresist composition include a rotation chuck, a first nozzle and a second nozzle. The rotation chuck holds the semiconductor substrate and then rotates the semiconductor substrate. The first nozzle supplies a thinner onto the semiconductor substrate while the second nozzle supplies the photoresist composition onto the semiconductor substrate.

In general, supplying the thinner to the semiconductor substrate first has been found to increase the efficient application of the photoresist composition to the semiconductor substrate. As a result, the amount of the photoresist composition required for forming the photoresist layer may be reduced.

A drawback with the above method is that the first-applied thinner, when supplied at a different temperature than that of the photoresist composition, results in the photoresist layer being unevenly distributed across the wafer. That is, the thickness uniformity of the photoresist layer is reduced.

While the first and second nozzles may be moved to subsequently supply the thinner and the photoresist composition onto all areas of the semiconductor, such a process has the disadvantage of being quite time intensive.

Accordingly, the need exists for a solution supplying device capable of rapidly forming a photoresist layer having relatively high thickness uniformity.

### SUMMARY OF THE INVENTION

A solution supplying device constructed according to a preferred embodiment of the invention comprises a first nozzle supplying a thinner onto a substrate, a second nozzle supplying a photoresist composition onto the substrate where the second nozzle is provided in the first nozzle, a first pipe connected to the first nozzle through which the thinner flows, a second pipe connected to the second nozzle through which the photoresist composition flows, and a temperature controlling part enclosing the first pipe and the second pipe. The temperature controlling part includes a temperature controlling medium flowing therein and acts to maintain the thinner and the photoresist composition at constant and equivalent temperatures.

According to other aspects of the invention, the solution supplying device comprises a nozzle block having an inner space where a thinner is received. A first nozzle, supplying the thinner received in the inner space onto a substrate, downwardly extends from a lower face of the nozzle block. A second nozzle, supplying a photoresist composition onto the substrate, downwardly extends from a ceiling face of the inner space through the inner space and the first nozzle. A first supply part, supplying the thinner into the inner space, connects to an upper face of the nozzle block. Finally, a second supply part, supplying the photoresist composition into the second nozzle, connects to the upper face of the nozzle block.

In yet anther aspect of the invention a solution supplying device comprises a first supply port coupled to a first solution supply line and a second supply port, substantially co-axial with the first supply port, coupled to a second solution supply line. A temperature control part is coupled with said first and second supply line to maintain a temperature of solution exiting said first and second supply ports at a predetermined temperature. In a preferred embodiment, the temperature control part includes a pipe enclosing said first and second solution supply lines and having a temperature controlling medium circulating therethrough.

Finally, the invention comprises a method for applying a photoresist composition material of uniform thickness to a semiconductor substrate. The method involves rotating a semiconductor wafer about an axis of rotation and positioning a first port and a substantially co-axial second solution supply port over the rotating wafer surface at the axis of rotation. Thinner solution is then supplied through the first port to the rotating wafer and allowed to spread over the surface of wafer by action of centrifugal force. Photoresist material is then supplied through the second port to the rotating wafer and allowed also to spread over the surface of the wafer by action of centrifugal force. Both the thinner solution and photoresist material are maintained at an equivalent constant temperature over the course of the supplying step.

According to the present invention as above, the temperature of the thinner that is supplied onto the semiconductor substrate may be the same as the temperature of the photoresist composition. Therefore, a photoresist film having a uniform thickness may be formed. Further, since the second nozzle is disposed in the first nozzle, moving the first and second nozzles for supplying the thinner and the photoresist composition is unnecessary. Thus, the time for forming the photoresist film may be reduced.

### BRIEF DESCRIPTION OF THE DRAWINGS

The above and other advantages of the present invention will become readily apparent by reference to the following detailed description when considered in conjunction with the accompanying drawings in which:

FIG. 1 is a cross-sectional view illustrating a solution supplying device in accordance with a preferred embodiment of the present invention; and

FIG. 2 is a cross-sectional view illustrating a solution supplying device in accordance with an alternate embodiment of the present invention.

### DESCRIPTION OF THE EMBODIMENTS

Embodiments of the present invention will be described with reference to the accompanying drawings. The present invention may, however, be embodied in many different forms and should not be construed as limited to the embodiments set forth herein. Rather, the embodiments are provided so that disclosure of the present invention will be thorough and complete, and will fully convey the scope of the present invention to those skilled in the art. The principles and features of this invention may be employed in varied and numerous embodiments without departing from the scope of the present invention. In the drawings, the sizes and relative sizes of layers and regions may be exaggerated for clarity. The drawings are not to scale. Like reference numerals refer to like elements throughout.

It will be understood that when an element or layer is referred to as being “on,” “connected to” and/or “coupled to” another element or layer, the element or layer may be directly on, connected and/or coupled to the other element or layer or intervening elements or layers may be present. In contrast, when an element is referred to as being “directly on,” “directly connected to” and/or “directly coupled to” another element or layer, there may be no intervening elements or layers present. As used herein, the term “and/or” may include any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms may be used to distinguish one element, component, region, layer and/or section from another element, component, region, layer and/or section. For example, a first element, component, region, layer and/or section discussed below could be termed a second element, component, region, layer and/or section without departing from the teachings of the present invention.

Spatially relative terms, such as “beneath,” “below,” “lower,” “above,” “upper” and the like may be used to describe an element and/or feature's relationship to another element(s) and/or feature(s) as illustrated in the figures. It will be understood that the spatially relative terms are intended to encompass different orientations of the device in use and/or operation in addition to the orientation depicted in the figures. For example, if the device in the figures is turned over, elements described as “below” and/or “beneath” other elements or features would then be oriented “above” the other elements or features. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular terms “a,” “an” and “the” are intended to include the plural forms as well, unless the context clearly indicates otherwise. It will be further understood that the terms “includes” and/or “including,” when used in this specification, specify the presence of stated features, integers, steps, operations, elements, and/or components, but do not preclude the presence and/or addition of one or more other features, integers, steps, operations, elements, components, and/or groups thereof.

Unless otherwise defined, all terms (including technical and scientific terms) used herein may have the same meaning as commonly understood by one of ordinary skill in the art. It will be further understood that terms, such as those defined in commonly used dictionaries, should be interpreted as having a meaning that is consistent with their meaning in the context of the relevant art and will not be interpreted in an idealized and/or overly formal sense unless expressly so defined herein.

Embodiments of the present invention are described with reference to cross-section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an etched region illustrated as a rectangle will, typically, have rounded or curved features. Thus, the regions illustrated in the figures are schematic in nature of a device and are not intended to limit the scope of the present invention.

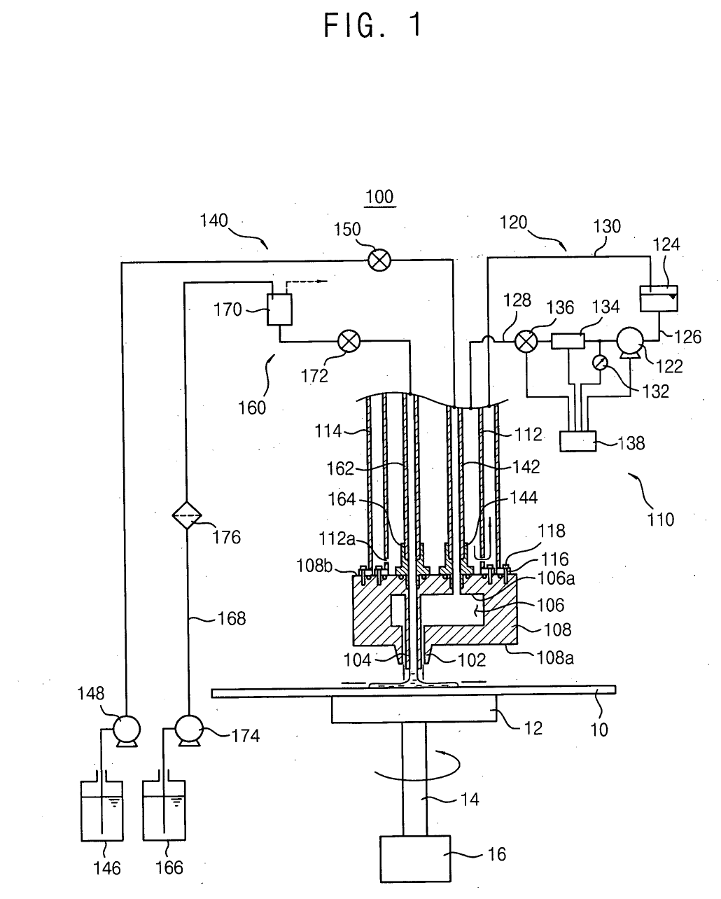

FIG. 1 is a cross-sectional view illustrating a solution supplying device in accordance with a preferred embodiment of the present invention.

Referring to FIG. 1, a solution supplying device 100 may be used to coat a semiconductor substrate 10, such as a silicon wafer, with a photoresist composition. A rotation chuck 12 is provided at a lower portion of the solution supplying device 100 to hold the semiconductor substrate 10 by using a vacuum pressure and rotate the semiconductor substrate 10. A rotation axis 14 is connected between the rotation chuck 12 and a first drive portion 16 so that a rotation force generated from the first drive portion 16 may be transferred to the rotation chuck 12.

The solution supplying device 100 includes a first nozzle 102, a second nozzle 104 and a temperature controlling part 110. The first nozzle 102 may be used for providing the semiconductor substrate 100 with a thinner. The second nozzle 104 may be used for providing the semiconductor substrate 100 with the photoresist composition. The temperature controlling part 110 may be used for constantly maintaining temperatures of the thinner and the photoresist composition.

A nozzle block 108 is provided over the rotation chuck 12. The nozzle block 108 has an inner space 106 where the thinner is stored. The first nozzle 102 downwardly extends from a lower face 108a of the nozzle block 108. The first nozzle 102 is communicated with the inner space 106.

A second nozzle 104 is provided inside the first nozzle 102 and the inner space 106 of the nozzle block 108. In detail, the second nozzle 104 extends from a ceiling face 106a of the nozzle block 108. The second nozzle 104 downwardly extends through the inner space 106 and the first nozzle 102. The first and the second nozzles 102 and 104 may be substantially coaxial.

As illustrated in FIG. 1, the first and second nozzles 102 and 104 are integrally formed with the nozzle block 108. Alternatively, the first nozzle 102 and the second nozzle 104 are separately formed from the nozzle block 108 with which the first and second nozzles 102 and 104 are then combined. In some embodiments, the first and second nozzles 102 and 104 are tightly fitted to the nozzle block 108. In further embodiments of the present invention, the first and second nozzles 102 and 104 are combined with the nozzle block 108 by using at least one screw.

First and second supply parts 140 and 160 are connected to an upper face 108b of the nozzle block 108. The first supply part 140 provides the nozzle block 108 with the thinner. The second supply part 160 provides the nozzle block 108 with the photoresist composition.

Particularly, a first pipe 142 used as a passage of the thinner is connected to the upper face 108b of the nozzle block 108 by using a first connection member 144. A second pipe 162 used as a passage of the photoresist composition is connected to the upper face 108b of the nozzle block 108 by using a second connection member 164. The first pipe 142 is communicated with the inner space 106 of the nozzle block 108. The second pipe 164 is communicated with the second nozzle 104. At least one sealing member may be provided between the first connection member 144 and the nozzle block 108. At least one sealing member may be also provided between the second connection member 164 and the nozzle block 108. The sealing member may be an O-ring.

The thinner provided from the first pipe 142 into the inner space 106 may be provided toward a central portion of the semiconductor substrate 10 supported on the rotation chuck 12 through the first nozzle 102.

The first pipe 142 is connected between the nozzle block 108 and a first storage 146 that stores the thinner. A first valve 150 and a first pump 148 are provided on the first pipe 142. The first pump 148 may pump the thinner stored in the first storage 146 into the first pipe 142. The first valve 150 may control a flow rate of the thinner provided into the inner space 106.

The second pipe 162 and a connection pipe 168 are connected between the second nozzle 104 and a second storage 166 that stores the photoresist composition. In detail, the second pipe 162 is connected between the second nozzle 104 and a buffer tank 170. The buffer tank 170 temporarily stores the photoresist composition to remove bubbles from the photoresist composition. The connection pipe 168 is connected between the second storage 166 and the buffer tank 170. A second valve 172 is provided on the second pipe 162 to control a flow rate of the photoresist composition. A second pump 174 and a filter 176 are provided on the connection pipe 168. The second pump 174 may pump the photoresist composition stored in the second storage 166 into the connection pipe 168. The filter 176 may remove impurities from the photoresist composition.

In addition, the first valve 150 and the second valve 172 may be used to vacuum remove excess solution from the semiconductor substrate. In detail, after the thinner is provided from the first nozzle 102 toward the central portion of the semiconductor substrate 10, the first valve 150 extracts the remaining thinner into the first nozzle 102. After the photoresist composition is provided from the second nozzle 104, the second valve 172 extracts the remaining photoresist composition into the second nozzle 104. Accordingly, when solid residues of the photoresist composition reside on an end portion of the second valve 104, the solid residues may be removed by repeatedly injecting and then extracting the thinner and the photoresist composition.

Many apparent variations of elements used for providing the thinner and the photoresist composition are possible without departing from the spirit or scope of the present invention.

The temperature controlling part 110 circulates a temperature controlling medium to constantly maintain a temperature of the thinner and the photoresist composition that flow respectively through the first and second pipes 142 and 162. The temperature controlling medium may be water. The temperature controlling medium may be circulated through an inner pipe 112 and an outer pipe 114. The inner pipe 112 may enclose the first and second pipes 142 and 162. The outer pipe 114 may enclose the inner pipe 112. Particularly, the inner pipe 112 and the outer pipe 114 may be connected to the upper face 108b of the nozzle block 108. The inner pipe 112 may be provided in the outer pipe 114. The first and second pipes 142 and 162 are provided in the inner pipe 112. A plurality of holes 112a is formed through an end portion of the inner pipe 112, the end portion being adjacent to the nozzle block 108, so that the temperature controlling medium may be circulated. Circulation pipes connect the inner pipe 112 and the outer pipe 114 to a medium circulation part 120. End portions of the inner pipe 112 and the outer pipe 114 are connected to ring-shaped flanges 116. The ring-shaped flanges 116 are combined with the nozzle block 108 by using a plurality of bolts 118. In addition, as illustrated in FIG. 1, sealing members such as O-rings may be interposed between the ring-shaped flanges 116 and the upper face 108b of the nozzle block 108 to reduce the chance of leakage of the temperature controlling medium between the ring-shaped flanges 116 and the upper face 108b of the nozzle block 108.

The medium circulation part 120 is connected to portions of the inner pipe 112 and the outer pipe 114 that are apart from the nozzle block 108. Particularly, the medium circulation part 120 includes a circulation pump 122, a third storage 124, a first circulation pipe 126, a second circulation pipe 128 and a third circulation pipe 130. The circulation pump 122 circulates the temperature controlling medium. The third storage 124 stores the temperature controlling medium.

The first circulation pipe 126 is connected between the third storage 124 and the circulation pump 122. The second circulation pipe 128 is connected between the circulation pump 122 and the inner pipe 112. The third circulation pipe 130 is connected between the outer pipe 114 and the third storage 124. The circulation pump 122 may pump the temperature controlling medium so that the temperature controlling medium may flow from the third storage 124 into the inner pipe 112 through the first and second pipes 126 and 128. The temperature controlling medium may maintain temperatures of the thinner and the photoresist composition that flow respectively through the first pipe 142 and the second pipe 162 constant.

The circulation pattern of the temperature controlling medium first flows through inner pipe 112, and thence into the outer pipe 112 through the holes 112a of the inner pipe 112. The temperature controlling medium is stored again in the third storage 124 through the third circulation pipe 130.

Alternatively, the temperature controlling medium may flow from the outer pipe 114 into the inner pipe 112. In this case, the second circulation pipe 128 may be connected between the circulation pump 122 and the outer pipe 114. The third circulation pipe 130 may be connected between the inner pipe 112 and the third storage 124.

A temperature sensor 132, a heat exchanger 134 and a third valve 136 may be provided on the second circulation pipe 128. The temperature sensor 132 measures the temperature of the temperature controlling medium. The heat exchanger 134 controls the temperature of the temperature controlling medium. The third valve 136 controls a flow rate of the temperature controlling medium. A control portion 138 is connected to the circulation pump 122, the temperature sensor 132, the heat exchanger 134 and the third valve 136 so that the control portion 138 may control the third valve 136 and the heat exchanger 134 in accordance with the temperature measured by the temperature sensor 132. For example, the control portion 138 may control the amount of opening of the third valve 136 and an operation of the heat exchanger 134.

The temperature controlling medium constantly maintains a temperature of the thinner and the photoresist composition that flow through the first pipe 142 and the second pipe 162, respectively. As one example, the temperatures of the thinner and the photoresist composition may be kept constant between about 22° C. to about 24° C. As another example, the temperatures of the thinner and the photoresist composition may be kept constant at about 23° C.

The photoresist composition may include a photosensitive resin and a solvent. The thinner may be substantially the same as the solvent included in the photoresist composition.

The nozzle block 108 may be combined with a second drive portion (not shown). The second drive portion may move the nozzle block 108 vertically or horizontally. The second drive portion may include a Cartesian coordinates robot or a selective compliance assembly robot arm (SCARA) type robot.

Methods of forming a photoresist layer on a semiconductor substrate 10 by using a solution supplying device 100 are hereinafter described with reference to the drawings.

The semiconductor substrate 10 is transferred onto a rotation chuck 12 by a transfer device (not shown). The semiconductor substrate 10 transferred onto the rotation chuck 12 is held on the rotation chuck 12 by using a vacuum pressure. Here, a center of the semiconductor substrate 10 may be positioned on a central axis of the rotation chuck 12. When the semiconductor substrate 10 is transferred, first and second nozzles 102 and 104 are positioned beside the rotation chuck 12. A temperature of the semiconductor substrate 10 and a temperature of an inner space of a chamber are kept constant at a predetermined temperature. In detail, the temperature of the semiconductor substrate 10 may be controlled at a first temperature before the semiconductor substrate 10 is transferred onto the rotation chuck 12. For example, the first temperature is about 23° C. While the photoresist layer is formed on the semiconductor substrate 10 in the chamber, the temperature of the inner space of the chamber may be kept constant at a second temperature. For example, the second temperature is substantially the same as the first temperature.

After the semiconductor substrate 10 is transferred onto the rotation chuck 12, the second drive portion moves the first and second nozzles 102 and 104 over a central portion of the semiconductor substrate 10 that is held on the rotation chuck 12. The first drive portion 16 rotates the semiconductor substrate 10 at a predetermined speed of rotation.

After the substrate 10 is spun up, a thinner is provided onto the semiconductor substrate 10 through the first nozzle 102 so that an adhesion between a surface of the semiconductor substrate 10 and the photoresist composition may be improved. The thinner is provided at a flow rate of about 80 ml/min for about 3 seconds.

After the thinner is provided onto the semiconductor substrate 10, the predetermined amount of the photoresist composition is provided onto the semiconductor substrate 10 through the second nozzle 104. For example, a photoresist composition of about 1.5 cc may be provided on to the silicon wafer having a diameter of about 300 mm to form a photoresist layer on the silicon wafer. The photoresist composition provided onto the semiconductor substrate 10 forms a photoresist layer having a substantially uniform thickness with the aid of a centrifugal force. Here, the speed of rotation of the semiconductor substrate 10 may be about 1500 rpm.

As described above, the temperature of the thinner is maintained constantly at the temperature of the photoresist composition with the aid of a circulating temperature controlling medium. For example, the temperature of the photoresist composition is about 23° C. Because the temperature of the semiconductor substrate 10 is substantially similar to that of the thinner added previously, the substrate is maintained at a uniform temperature and, therefore, the applied photoresist layer results in a uniformly applied thickness. In addition, there is no need to move the first and second nozzles 102 and 104 for providing the photoresist composition after the thinner is provided because one is co-axial with the other and thus positioned over the same (e.g. central) portion of the wafer. Thus, a time required for forming the photoresist layer is reduced.

After the photoresist layer is formed on the semiconductor substrate 10, the first and second nozzles 102 and 104 are transferred to a position beside the rotation chuck 12 by the second drive portion. The semiconductor substrate 10 may be then unloaded from the rotation chuck 12 by the transfer device.

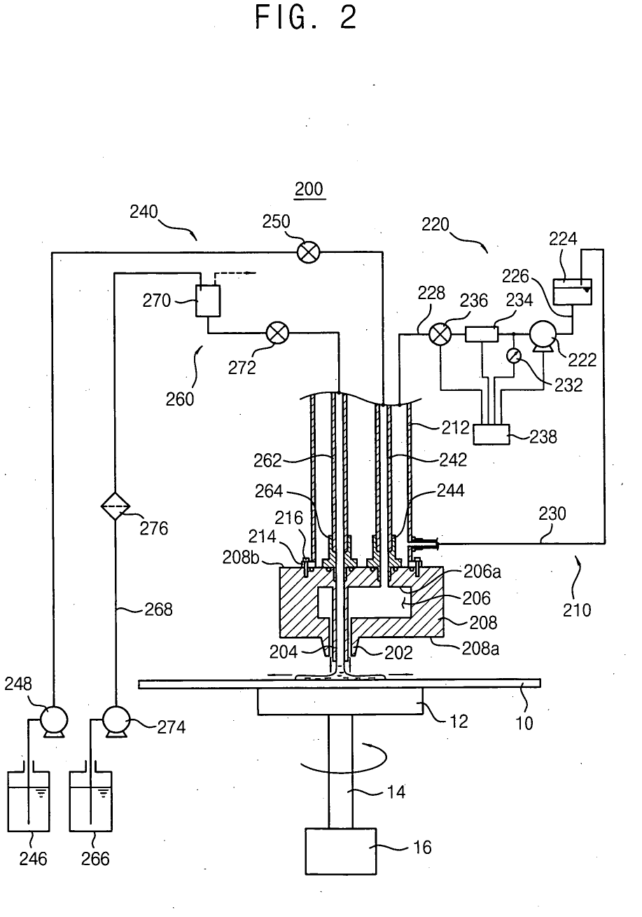

FIG. 2 is a cross-sectional view illustrating a solution supplying device in accordance with an alternate embodiment of the present invention.

Referring to FIG. 2, a solution supplying device 200 may include a first nozzle 202, a second nozzle 204 and a temperature controlling part 210. The first nozzle 202 may be used for providing a semiconductor substrate 10 with a thinner. The second nozzle 204 may be used for providing the semiconductor substrate 10 with a photoresist composition. The temperature controlling part 210 may be used for keeping temperatures of the thinner and the photoresist composition constant.

The semiconductor substrate 10 is held on a rotation chuck 12. A rotation axis 14 is connected between the rotation chuck 12 and a first driving portion 16 that generates a rotation force so that the rotation chuck 12 may be rotated by the rotation force. That is, the first drive portion 16 provides the rotation force with the rotation chuck 12 through the rotation axis 14 connected between the rotation chuck 12 and the first drive portion 16. A nozzle block 208 having an inner space 206 in which the thinner is received is provided over the rotation chuck 12. The first nozzle 202 downwardly extends from a lower face 208a of the nozzle block 208. In addition, the first nozzle 202 is communicated with the inner space 206 of the nozzle block 208. The second nozzle 204 is provided in the inner space 206 and the first nozzle 202. In detail, the second nozzle 204 downwardly extends from a ceiling face 206a of the nozzle block 208 through the inner space 206 and the first nozzle 202. The ceiling face 206a may define the inner space 206.

A first supply part 240 for supplying the thinner and a second supply part 260 for supplying the photoresist composition may be connected to the nozzle block 208. In detail, a first pipe 242 used as a passage of the thinner is connected to the upper face 208b of the nozzle block 208 by using a first connection member 244. A second pipe 262 used as a passage of the photoresist composition is connected to the upper face 208b of the nozzle block 208 by using a second connection member 264.

The first pipe 242 may be connected between a first storage 246 and the nozzle block 208. The first storage 246 stores the thinner. A first pump 248 and a first valve 250 are provided on the first pipe 242. The first pump 248 may pump the thinner stored in the first storage into the first pipe 242. The first valve 250 is used for controlling a flow rate of the thinner. A second pipe 262 and a connection pipe 268 are connected between the second nozzle 204 and a second storage 266 that stores the photoresist composition. In detail, the second pipe 262 is connected between the second nozzle 204 and a buffer tank 270.

The connection pipe 268 is connected between the second storage 266 and the buffer tank 270. A second valve 272 is provided on the second pipe 262. The second valve 272 may be used for controlling a flow rate of the photoresist composition. A second pump 274 and a filter 276 are provided on the connection pipe 268.

The above-described elements are substantially the same as those already described with reference to FIG. 1. Thus, any further explanation will be omitted.

The temperature controlling part 210 circulates a temperature controlling medium so that a temperature of the thinner flowing through the first pipe 242 may be substantially the same as that of the photoresist composition flowing through the second pipe 262. The temperature controlling medium may be water. The temperature controlling medium may be circulated through a third pipe 212 enclosing the first pipe 242 and the second pipe 262.

In detail, the third pipe 212 is combined with an upper face 208b of the nozzle block 208. The first pipe 242 and the second pipe 262 are provided in the third pipe 212. In addition, a ring-shaped flange 214 may be provided at a lower portion of the third pipe 212 and combined with the nozzle block 208 by using a plurality of bolts 216.

A medium circulation part 220 is connected to upper and lower portions of the third pipe 212 so that the medium circulation part 220 may efficiently circulate the temperature controlling medium. In detail, the medium circulation part 220 may include a circulation pump 222, a third storage 224, a first circulation pipe 226, a second circulation pipe 228 and a third circulation pipe 230.

The circulation pump 222 is used for circulating the temperature controlling medium. The third storage 224 stores the temperature controlling medium. The first circulation pipe 226 is connected between the third storage 224 and the circulation pump 222. The second circulation pipe 228 is connected between the circulation pump 222 and the upper portion of the third pipe 212. The third circulation pipe 230 is connected between the lower portion of the third pipe 212 and the third storage 224. The circulation pump 222 may pump the temperature controlling medium so that the temperature controlling medium may flow from the upper portion of the third pipe 212 to the lower portion of the third pipe 212 through the first and second circulation pipes 226 and 228 although it is understood (see below) that the process could work in reverse. Thus, temperatures of the thinner and the photoresist composition that flow respectively through the first pipe 242 and the second pipe 262 that are provided in the third pipe 212 may be kept constant.

Alternatively, the temperature controlling medium may flow from the lower portion of the third pipe 212 to the upper portion of the third pipe 212. In this case, the second circulation pipe 228 may be connected between the circulation pump 222 and the lower portion of the third pipe 212. The third circulation pipe 230 may be connected between the upper portion of the third pipe 212 and the third storage 224.

A temperature sensor 232, a heat exchanger 234 and a third valve 236 are provided on the second circulation pipe 228. The temperature sensor 232 measures a temperature of the temperature controlling medium. The heat exchanger 234 controls the temperature of the temperature controlling medium. The third valve 236 controls a flow rate of the temperature controlling medium. A control portion 238 controls the third valve 236 and the heat exchanger 234, for example, by controlling the amount of opening of the third valve 236 and the operation of the heat exchanger 234.

The temperature controlling medium flowing through the third pipe 212 may enable temperatures of the thinner and the photoresist composition to be kept constant and equivalent at a predetermined temperature. As one example, the temperatures of the thinner and the photoresist composition are kept constant between about 22° C. and about 24° C. As another example, the temperature of the thinner and the photoresist composition are kept constant at about 23° C.

According to the present invention, temperatures of the thinner and photoresist composition that are provided onto a semiconductor substrate may be kept constant with the aid of a circulation of a temperature controlling medium. Thus, a photoresist layer having relatively high thickness uniformity may be efficiently formed.

In addition, a second nozzle for providing the photoresist composition may be provided in the first nozzle for providing the thinner so that the first and second nozzles need not be moved in order to provide the photoresist composition after the thinner is provided. Thus, a time required for forming the photoresist layer on the semiconductor substrate may be reduced.

The foregoing is illustrative of the present invention and is not to be construed as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

What is claimed is:

1. A solution supplying device comprising:
a first nozzle supplying a thinner onto a substrate;
a second nozzle supplying a photoresist composition onto the substrate, the second nozzle being provided in the first nozzle;
a first pipe connected to the first nozzle, the first pipe being where the thinner flows;
a second pipe connected to the second nozzle, the second pipe being where the photoresist composition flows; and
a temperature controlling part enclosing the first pipe and the second pipe, the temperature controlling part being where a temperature controlling medium flows, the temperature controlling part allowing the thinner and the photoresist composition to have temperatures that are substantially the same as each other, the temperature controlling part keeping the temperatures relatively constant.

2. The device of claim 1, further comprising a nozzle block having an inner space where the thinner is received, and
wherein the first nozzle downwardly extends from a lower face of the nozzle block, the first nozzle being communicated with the inner space,
wherein the second nozzle downwardly extends from a ceiling face of the inner space through the inner space and the first nozzle, and
wherein the first and second pipes are connected to an upper face of the nozzle block to be communicated respectively with the inner space and the second nozzle.

3. The device of claim 2, wherein the first and second nozzles are integrally formed with the nozzle block.

4. The device of claim 1, wherein the temperature controlling part comprises:
an inner pipe enclosing the first and second pipes;
an outer pipe enclosing the inner pipe; and
a medium circulation part circulating the temperature controlling medium through the inner pipe and the outer pipe.

5. The device of claim 4, wherein the medium circulation part comprises:
a circulation pump pumping the temperature controlling medium to circulate the temperature controlling medium;
a storage storing the temperature controlling medium;
a first circulation pipe connected between the storage and the circulation pump;
a second circulation pipe connected between the circulation pump and the inner pipe; and
a third circulation pipe connected between the storage and the outer pipe.

6. The device of claim 5, further comprising:
a temperature sensor measuring a temperature of the temperature controlling medium;
a valve controlling a flow rate of the temperature controlling medium;
a heat exchanger controlling the temperature of the temperature controlling medium; and
a controlling part controlling the amount of opening of the valve and an operation of the heat exchanger in accordance with the temperature of the temperature controlling medium, the temperature being measured by the temperature sensor.

7. The device of claim 4, wherein the medium circulation part comprises:
a circulation pump pumping the temperature controlling medium to circulate the temperature controlling medium;
a storage storing the temperature controlling medium;
a first circulation pipe connected between the storage and the circulation pump;
a second circulation pipe connected between the circulation pump and the outer pipe; and
a third circulation pipe connected between the storage and the inner pipe.

8. The device of claim 7, further comprising:
a temperature sensor measuring a temperature of the temperature controlling medium;
a valve controlling a flow rate of the temperature controlling medium;
a heat exchanger controlling the temperature of the temperature controlling medium; and
a controlling part controlling the amount of opening of the valve and an operation of the heat exchanger in accordance with the temperature of the temperature controlling medium, the temperature being measured by the temperature sensor.

9. The device of claim 4, wherein the inner pipe and the outer pipe are connected to the upper face of the nozzle block, the inner pipe including a plurality of holes formed through an end portion of the inner pipe adjacent to the upper face of the nozzle block to enable circulation of the temperature controlling medium between the inner and outer pipe.

10. The device of claim 2, wherein the temperature controlling part comprises:
a third pipe enclosing the first and second pipes, the third pipe connected to the upper face of the nozzle block; and
a medium circulation part circulating the temperature controlling medium through the third pipe.

11. The device of claim 10, wherein the medium circulation part comprises:
a circulation pump pumping the temperature controlling medium to circulate the temperature controlling medium;
a storage storing the temperature controlling medium;
a first circulation pipe connected between the storage and the circulation pump;
a second circulation pipe connected between the circulation pump and an upper portion of the third pipe; and
a third circulation pipe connected between the storage and a lower portion of the third pipe.

12. The device of claim 11, further comprising:
a temperature sensor measuring a temperature of the temperature controlling medium;
a valve controlling a flow rate of the temperature controlling medium;
a heat exchanger controlling the temperature of the temperature controlling medium; and
a control portion controlling the amount of opening of the valve and an operation of the heat exchanger in accordance with the temperature of the temperature controlling medium, the temperature being measured by the temperature sensor.

13. The device of claim 10, wherein the medium circulation part comprises:
a circulation pump pumping the temperature controlling medium to circulate the temperature controlling medium;
a storage storing the temperature controlling medium;
a first circulation pipe connected between the storage and the circulation pump;
a second circulation pipe connected between the circulation pump and a lower portion of the third pipe; and
a third circulation pipe connected between the storage and an upper portion of the third pipe.

14. The device of claim 13, further comprising:
a temperature sensor measuring a temperature of the temperature controlling medium;
a valve controlling a flow rate of the temperature controlling medium;
a heat exchanger controlling the temperature of the temperature controlling medium; and
a control portion controlling the amount of opening of the valve and an operation of the heat exchanger in accordance with the temperature of the temperature controlling medium, the temperature being measured by the temperature sensor.

15. A solution supplying device comprising:
a nozzle block having an inner space where a thinner is received;
a first nozzle downwardly extending from a lower face of the nozzle block, the first nozzle supplying the thinner received in the inner space onto a substrate;
a second nozzle downwardly extending from a ceiling face of the inner space through the inner space and the first nozzle, the second nozzle supplying a photoresist composition onto the substrate;
a first supply part connected to an upper face of the nozzle block, the first supply part supplying the thinner into the inner space; and
a second supply part connected to the upper face of the nozzle block, the second supply part supplying the photoresist composition into the second nozzle.

16. The device of claim 15, wherein the first supply part comprises:
a storage storing the thinner;
a pipe connected between the storage and the nozzle block; and
a pump provided on the pipe, the pump pumping the thinner into the inner space.

17. The device of claim 16, wherein the first supply part comprises a valve provided on the pipe, the valve controlling a flow rate of the thinner.

18. The device of claim 15, wherein the second supply part comprises:
a storage storing the photoresist composition;
a buffer tank temporarily storing the photoresist composition to remove bubbles from the photoresist composition;
a first pipe connected between the storage and the buffer tank;
a second pipe connected between the buffer tank and the nozzle block; and
a pump provided on the first pipe to pump the photoresist composition.

19. The device of claim 18, wherein the second supply part comprises:
a filter provided on the first pipe to remove impurities from the photoresist composition; and
a valve provided on the second pipe to control a flow rate of the photoresist composition.

20. A solution supplying device comprising:
a first supply port coupled to a first solution supply line;
a second supply port, substantially co-axial with the first supply port, coupled to a second solution supply line; and
a temperature control part coupled with said first and second supply line to maintain a temperature of solution exiting said first and second supply ports at a predetermined temperature.

21. The solution supplying device of claim 20, wherein a photoresist composition and a thinner are run through said first and second supply line, respectively.

22. The solution supplying device of claim 21, said first supply port being an inner port and said second supply port being an outer port surrounding said inner port.

23. The solution supplying device of claim 22, further including a rotating wafer positioned below said supplying device wherein a rotational axis of said wafer is positioned immediately below said substantially co-axial first and second supply ports so that thinner and photoresist solution supplied to the wafer through the ports is spread by centrifugal force across a top surface of the wafer to which the solution is supplied.

24. The solution supplying device of claim 20, said temperature control part including a pipe enclosing said first and second solution supply lines and having a temperature controlling medium circulating therethrough.

25. The solution supplying device of claim 24, said pipe comprising an inner pipe enclosing said first and second solution supply lines and an outer pipe enclosing said inner pipe, said temperature controlling medium circulating between said inner pipe and said outer pipe.

26. The solution supplying device of claim 24, further comprising:
a temperature sensor measuring a temperature of the temperature controlling medium;
a valve controlling a flow rate of the temperature controlling medium through the pipe;
a heat exchanger controlling the temperature of the temperature controlling medium; and
a controlling part controlling the amount of opening of the valve and the operation of the heat exchanger in accordance with the temperature of the temperature controlling medium, the temperature being measured by the temperature sensor.

27. The solution supplying device of claim 26, said temperature controlling medium maintained at a temperature of between about 22° C. to 24° C.

28. The solution supplying device of claim 27, said temperature controlling medium maintained at a temperature of about 23° C.

29. The solution supplying device of claim 24, wherein said temperature controlling medium is water.

30. A method for applying a photoresist composition material of uniform thickness to a semiconductor substrate comprising:
rotating a semiconductor wafer about an axis of rotation;
positioning a first port and a substantially co-axial second solution supply port over the rotating wafer surface at the axis of rotation;
supplying a thinner solution through the first port to the rotating wafer and allowing the thinner solution to spread over the surface of wafer by action of centrifugal force;
then supplying a photoresist material through the second port to the rotating wafer and allowing the photoresist material to spread over the surface of the wafer by action of centrifugal force; and
maintaining the thinner solution and photoresist material at an equivalent constant temperature over the course of the supplying step.

31. The method of claim 39, wherein the step of maintaining the thinner solution and photoresist material at a constant temperature includes enclosing supply lines feeding the thinner solution and photoresist material to the first and second supply ports, respectively, with a common temperature controlling part.

32. The method of claim 30, further including flowing a temperature controlling medium through the temperature controlling part so that said temperature controlling medium comes in contact with said supply lines feeding the thinner solution and photoresist material to the first and second supply ports.

33. The method of claim 30, further including:
sensing a temperature of the temperature controlling medium; and
controlling a flow rate of the temperature controlling medium through the temperature controlling part and heating the temperature medium responsive to the sensing step.

34. The method of claim 30, wherein said equivalent constant temperature is between about 22° C. to 24° C.
